(19) United States
(12) Patent Application Publication
(10) Pub. No.: US 2019/0119806 A1
(43) Pub. Date: Apr. 25, 2019

(54) Method of Forming a Coating on a Substrate and an Article Formed by Such a Method

(71) Applicant: Vitalink Industry (Shenzhen) Co., Ltd., Shenzhen (CN)

(72) Inventors: Yan Fang ZHANG, Shenzhen (CN); Tao XUE, Shenzhen (CN); Hei Ping CHUNG, Shenzhen (CN); Sing Kai CHONG, Wan Chai (HK)

(73) Assignee: Vitalink Industry (Shenzhen) Co., Ltd.

(21) Appl. No.: 15/789,746

(22) Filed: Oct. 20, 2017

(51) Int. Cl. C23C 14/00; C23C 14/06; C23C 14/16; C23C 14/34; C23C 14/35; C23C 14/02

(52) U.S. Cl. CPC C23C 14/0057; C23C 14/0036; C23C 14/0641; C23C 14/0664; C23C 14/3464; C23C 14/352; C23C 14/022; C23C 14/165

(57) ABSTRACT

An article (10), e.g. a casing, is disclosed as including a substrate (12) made of a metal or a metal alloy, such as stainless steel, and a coating (14) deposited on the substrate (12), the coating (14) including a base layer (16) of titanium (Ti) or chromium (Cr) doped with silicon (Si) or boron (B) deposited on the substrate (12), a transition layer (18) of titanium nitride (TiN) deposited on the base layer (16), and an outer decorative coloured layer (20) deposited on the transition layer (18).

This invention relates to an article, a method of forming a coating on a substrate, and an article formed of such a method which is suitable for, but not limited to, use as a casing.

### BACKGROUND OF THE INVENTION

The use of a magnetron sputtering physical vapour deposition (PVD) technique in forming a coating (in particular a decorative coating) on a substrate has the advantages that the coating is of good adhesion, has a smooth and closely packed structure, is deposited with a high deposition speed, and may be carried out in a clean working environment. The decorative coating performs both decorative and protective functions.

With the continuous development of technology and the complexity of the conditions and environments of use of various products with coatings, there is an ever increasingly high demand on the quality of decorative coatings. Such demands do not only relate to the colour and outward appearance, but also to such other qualities as corrosion resistance, erosion resistance and chemical-stability.

Titanium (Ti) and titanium-alloy targets have been used in the field of the formation of decorative coatings, and have been used in reactive magnetron sputtering in the presence of such gases as methane (CH₄), acetylene (C₂H₂), nitrogen (N₂) and oxygen (O₂) to form decorative coatings of various colours, such as gun black, imitated gold, coffee, and rose gold. High quality coatings of titanium carbide (TiC), titanium nitride (TiN) and titanium carbo-nitride (TiCN) are of a high melting point, high hardness, and chemical stability and can satisfy the above requirements to a certain extent.

However, when forming titanium-based coatings by conventional magnetron sputtering methods, due to the small size of the particles and low ionization rate, the surface and transverse sectional view of the coating are (as shown in scanning electronic microscope (SEM) images) in the form of separated columns and/or pyramids with relatively large gaps therebetween. FIG. 1 is an SEM image of a conventional titanium-based decorative coating. Corrosive media may reach the substrate surface through the gaps between the columns and/or pyramids in the titanium-based coating, and may also damage the structure of the coating due to a primary cell effect.

It is thus an object of the present invention to provide an article, a method of forming a coating on a substrate, and an article formed of such a method in which the aforesaid shortcomings are mitigated or at least to provide a useful alternative to the trade and public.

### SUMMARY OF THE INVENTION

According to a first aspect of the present invention, there is provided an article including a substrate comprising a metal or a metal alloy, and a coating deposited on said substrate, wherein said coating includes at least a first layer including a metal doped with silicon (Si) or boron (B).

According to a second aspect of the present invention, there is provided a method of forming a coating on a substrate, including steps (a) providing a metal or metal alloy substrate, and (b) depositing a first layer of a coating on said substrate by sputtering a metal together with silicon (Si) or boron (B) onto said substrate.

According to a third aspect of the present invention, there is provided an article manufactured according to a method of forming a coating on a substrate, including steps (a) providing a metal or metal alloy substrate, and (b) depositing a first layer of a coating on said substrate by sputtering a metal together with silicon (Si) or boron (B) onto said substrate.

### BRIEF DESCRIPTION OF THE DRAWINGS

Embodiments of the present invention will now be described, by way of example only, with reference to the accompanying drawings, in which:

FIG. 1 is an SEM image of a conventional titanium-based decorative coating;

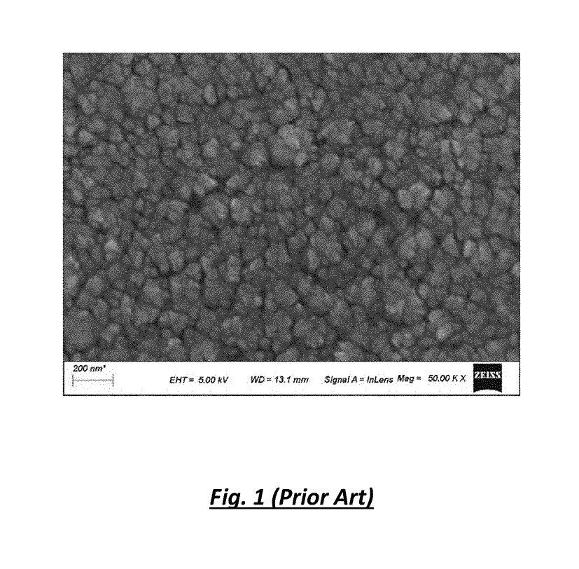

FIG. 2 is a schematic cross sectional view of a casing according to an embodiment of the present invention; and

FIG. 3 is an SEM image of a titanium-based decorative coating according to an embodiment of the present invention.

### DETAILED DESCRIPTION OF THE EMBODIMENTS

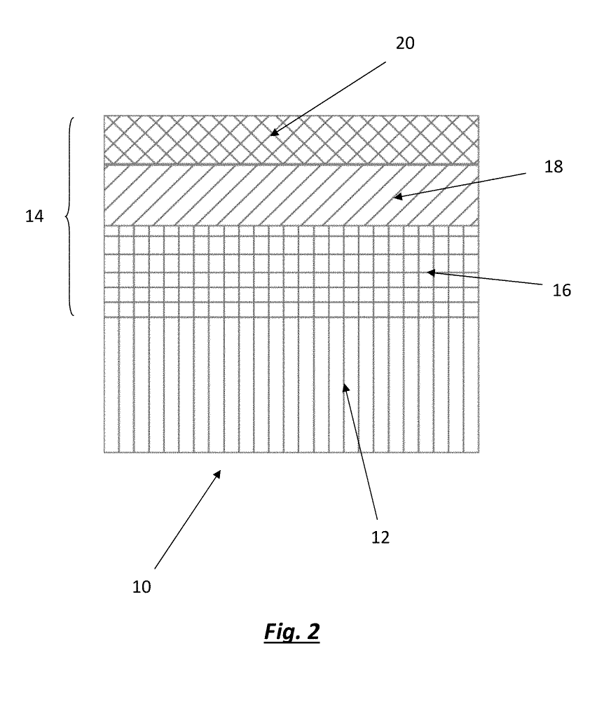

A schematic cross sectional view of an article (e.g. a casing for such products as watches, mobile phones, and tablet computers) with a coating according to the present invention is shown in FIG. 2, and generally designated as 10.

The article 10 has a substrate 12 made of a metal or a metal alloy, such as stainless steel. A coating 14 is deposited on the substrate 12. The coating 14 on this substrate 12 includes a total of three layers, namely a base layer 16, a transition later 18, and an outer decorative layer 20, with the base layer 16 deposited on the substrate 12, the transition layer 18 deposited on the base layer 16, and the outer decorative layer 20 deposited on the transition layer 18.

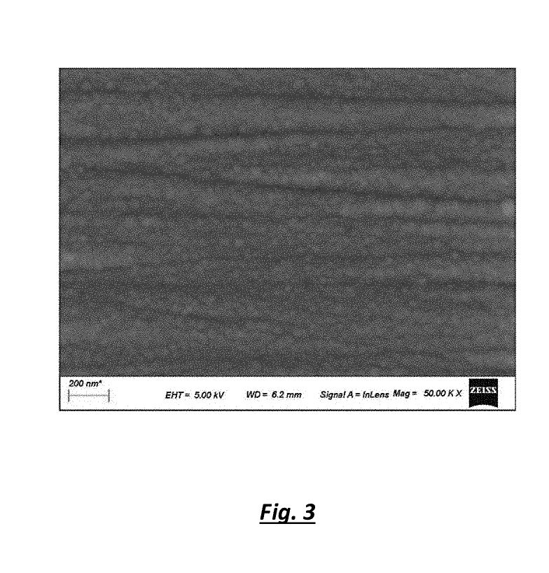

The base layer 16 is a layer of titanium (Ti) or chromium (Cr), which is doped with silicon (Si) or boron (B). The ratio of the number of titanium atoms or chromium atoms to the number of silicon atoms or boron atoms in the base layer 16 is from substantially 5:5 to substantially 8:2. As silicon and boron are capable of reducing the crystal size, the crystal of the metal base layer 16 as doped with silicon or boron is of a very small size and are dense and compact, even to the extent that the coating is non-crystallized, which provides a dense and planar interface suitable for deposition of other layer(s). FIG. 3 is an SEM image of a titanium-based decorative coating according to an embodiment of the present invention. Such a smooth and compact doped metal base layer 16 prevents corrosive media from reaching the surface of the substrate 12 and avoids damage to the structure of the coating by primary cell effect.

Generally speaking, a method of forming the coating 14 on the substrate 12 according to the present invention involves the following four stages:
(a) cleaning: removing dirt, grease and impurities from the surface of the substrate 12;
(b) coating: forming the coating 14 on the substrate 12;
(c) checking: checking the decorative quality of the coated article 10, such as outward appearance and colour; and
(d) testing: testing the reliability of the coated article 10, such as corrosion resistance and erosion resistance.

The general technical parameters of a method of forming the coating 14 on the substrate 12 according to the present invention are shown in Table 1 below.

TABLE 1

| | | | Deposition of | Deposition of |
|---|---|---|---|---|
| | Arc | Deposition of | Transition Layer | Outer Decorative |
| | Bombardment | Base Layer 16 | 18 | Layer 20 |
| Time (minutes) | 3-8 | 30-120 | 10-50 | 10-50 |
| Arc Titanium | 40-100 | — | — | — |
| Target Electric | | | | |
| Current (A) | | | | |
| Titanium Target | — | — | 4-12 | 4-12 |
| Power (kW) | | | | |
| TiSi/TiB Target | — | 4-12 | — | — |
| Power (kW) | | | | |
| Voltage Bias | 300-800 | 50-300 | 100-400 | 100-400 |
| (−V) | | | | |
| Argon Flowrate | 300-800 | 300-800 | 300-800 | 300-800 |
| (sccm) | | | | |
| N₂ Flowrate | — | — | 15-80 | 40-150 |
| (sccm) | | | | |
| C₂H₂ Flowrate | — | — | — | 10-40 |
| (sccm) | | | | |

Note:
“sccm” in Table 1 stands for “standard cubic centimeters per minute”, i.e. cm³/min.

### Example 1

A champagne-coloured titanium-based corrosion-resistant decorative coating 14 was formed on a stainless steel substrate 12 to form an article 10 (such as a casing for such products as watches, mobile phones, and tablet computers) of a structure generally as shown in FIG. 2. The base layer 16 deposited on the substrate 12 is of made of titanium (Ti) doped with silicon (Si), and of a thickness of 0.8 μm. The ratio between the number of Ti ions and the number of Si ions in the base layer 16 is 6:4. The transition layer 18 deposited on the base layer 16 is made of titanium nitride (TiN), and of a thickness of 0.4 μm. As to the decorative layer 20 deposited on the transition layer 18, such is of a thickness of 0.4 μm, and is mainly made of titanium, and was sputtered in the presence of suitable amounts of nitrogen (N₂) and acetylene (C₂H₂), so as to obtain the desired champagne colour.

The above champagne-coloured titanium-based corrosion-resistant decorative coating 14 was obtained by un-balanced magnetron sputtering deposition, involving the following steps:
(a) pre-cleaning the substrate 12, to remove dirt, grease and residue impurities from the surface of the substrate 12;
(b) placing the cleaned substrate 12 in the deposition chamber, lowering the pressure in the deposition chamber to not more than 8.0×10⁻³ Pa, and pre-heating the substrate 12 to 150° C. The temperature was kept constant during the entire coating process;
(c) carrying out arc target bombardment to activate and further clean the surface of the substrate 12. The arc target was titanium (Ti), with an electric current of 80 A, at a biased voltage of −500 V, with an argon flowrate of 400 sccm, and for 6 minutes;
(d) depositing the base layer 16 onto the substrate 12, by using a TiSi alloy target (although it is also possible to carry out co-sputtering or nano-stacking sputtering by using both a Ti target and a Si target). The ratio of the number of Ti atoms to the number of Si atoms was 6:4, with the target power being 8 kW, at a biased voltage of −100 V, with an argon flowrate of 400 sccm, and for 80 minutes;
(e) depositing the transition layer 18 onto the base layer 16, by using a Ti target set at a power of 8 kW, at a biased voltage of −100 V, with an argon flowrate of 400 sccm, a nitrogen flowrate of 30 sccm, and for 30 minutes;
(f) depositing the outer decorative layer 20 onto the transition layer 18, with a Ti target set at a power of 8 kW, at a biased voltage of −200 V, with an argon flowrate of 400 sccm, a nitrogen flowrate of 80 sccm, an acetylene flowrate of 20 sccm, and for 25 minutes; and
(g) carrying out colour measuring, appearance checking, and reliability testing.

### Example 2

A champagne-coloured titanium-based corrosion-resistant decorative coating 14 was formed on a stainless steel substrate 12 to form an article 10 (such as a casing for such products as watches, mobile phones, and tablet computers) of a structure generally as shown in FIG. 2. The base layer 16 deposited on the substrate 12 is of made of titanium (Ti) doped with boron (B), and of a thickness of 1.0 μm. The ratio between the number of Ti ions and the number of B ions in the base layer 16 is 7:3. The transition layer 18 deposited on the base layer 16 is made of titanium nitride (TiN), and of a thickness of 0.5 μm. As to the decorative layer 20 deposited on the transition layer 18, such is of a thickness of 0.3 μm, and is made of mainly of titanium, and was sputtered in the presence of suitable amounts of nitrogen (N₂) and acetylene (C₂H₂), so as to obtain the desired champagne colour.

The process for obtaining the article 10 according to Example 2 was similar to that of Example 1, except that the titanium-based base layer 16 of the coating 14 was doped with boron.

Table 2 below shows results of tests carried out on the article 10 according to Example 1, the article 10 according to Example 2, and a reference article. The reference article included a substrate deposited with a coating including a titanium-based base layer, a titanium-nitride transition layer and a titanium-based outer decorative layer, with the only difference being that the titanium-based base layer of the reference article was not doped with Si or B.

TABLE 2

| | | Artificial | Testing | | |
|---|---|---|---|---|---|
| | Salt Spray | Sweat | by 24 | Sea Water | Pool Water |
| | Test | Test | Chemicals | Test | Test |
| Example 1 | Pass | Pass | Pass | Pass | Pass |
| Example 2 | Pass | Pass | Pass | Pass | Pass |
| Reference | Pass | Pass | Fail in 6 | Fail | Fail |
| Article | | | Chemicals | | |

It should be understood that the above only illustrates examples whereby the present invention may be carried out, and that various modifications and/or alterations may be made thereto without departing from the spirit of the invention.

It should also be understood that certain features of the invention, which are, for clarity, described in the context of separate embodiments, may be provided in combination in a single embodiment. Conversely, various features of the invention which are, for brevity, described in the context of a single embodiment, may also be provided separately or in any appropriate sub-combinations.

1. An article including:
a substrate comprising a metal or a metal alloy, and
a coating deposited on said substrate,
wherein said coating includes at least a first layer including a metal doped with silicon (Si) or boron (B).

2. An article according to claim 1, wherein said metal in said first layer is titanium (Ti) or chromium (Cr).

3. An article according to claim 2, wherein a ratio of a number of titanium atoms or chromium atoms to a number of silicon atoms or boron atoms in said first layer is from substantially 5:5 to substantially 8:2.

4. An article according to claim 1, wherein said coating includes a second layer deposited on said first layer.

5. An article according to claim 4, wherein said second layer includes titanium nitride (TiN).

6. An article according to claim 4, wherein said coating includes a third layer deposited on said second layer.

7. An article according to claim 6, wherein said third layer is coloured.

8. An article according to claim 1, wherein said article is a casing.

9. A method of forming a coating on a substrate, including:
(a) providing a metal or metal alloy substrate, and
(b) depositing a first layer of a coating on said substrate by sputtering a metal together with silicon (Si) or boron (B) onto said substrate.

10. A method according to claim 9, wherein said metal sputtered in (b) is titanium (Ti) or chromium (Cr).

11. A method according to claim 10, wherein a ratio of a number of titanium atoms or chromium atoms to a number of silicon atoms or boron atoms in said first layer is from substantially 5:5 to substantially 8:2.

12. A method according to claim 9, further including (c) depositing a second layer of said coating on said first layer by sputtering titanium and nitrogen onto said first layer to form a layer of titanium nitride.

13. A method according to claim 12, further including (d) depositing a third layer of said coating on said second layer by sputtering titanium onto said second layer in presence nitrogen (N₂) and acetylene (C₂H₂).

14. A method according to claim 13, wherein said third layer is coloured.

15. A method according to claim 9, including (e), that is carried out prior to (a), arc bombarding said substrate by titanium in presence of argon (Ar).

16. An article manufactured according to the method of claim 9.

17. An article according to claim 16, wherein said article is a casing.
